(19) United States
(12) Patent Application Publication
(10) Pub. No.: US 2017/0158078 A1
(43) Pub. Date: Jun. 8, 2017

(54) APPARATUS AND METHOD FOR ESTIMATING STATE OF CHARGE OF VEHICLE BATTERY

(71) Applicants: HYUNDAI MOTOR COMPANY, Seoul (KR); KIA MOTORS CORPORATION, Seoul (KR)

(72) Inventors: Yu Seok KIM, Seoul (KR); Jae Hoon CHOI, Gunpo-si (KR); Dong Gun KIM, Gunpo-si (KR); Dong Gil HA, Yongin-si (KR); Hee Tae YANG, Seoul (KR); Suk Hyung KIM, Gunpo-si (KR); Do Kyoung LIM, Suwon-si (KR)

(21) Appl. No.: 15/210,316

(22) Filed: Jul. 14, 2016

(30) Foreign Application Priority Data
Dec. 2, 2015 (KR) 10-2015-0170948

(51) Int. Cl. B60L 11/18; B60R 16/033; H01M 10/44; G01R 31/36; H01M 10/0525; H01M 10/48

(52) U.S. Cl. CPC B60L 11/1861; H01M 10/0525; H01M 10/48; H01M 10/44; G01R 31/3648; G01R 31/3613; B60L 11/1809; B60R 16/033; H01M 2220/20

(57) ABSTRACT

An apparatus for estimating a state of charge (SOC) of a vehicle battery including a storage for storing a map, in which SOC corresponding to a charging current is recorded, according to a charging voltage, a converter for charging a lithium ion battery, a current sensor for detecting a charging current of the lithium ion battery, and a controller for retrieving the map corresponding to a charging voltage of the lithium ion battery from the storage and for extracting an SOC corresponding to the charging current detected by the current sensor from the retrieved map to estimate a SOC of the lithium ion battery.

### CROSS-REFERENCE TO RELATED APPLICATION

This application claims the benefit of priority to Korean Patent Application No. 10-2015-0170948, filed on Dec. 2, 2015 with the Korean Intellectual Property Office, the disclosure of which is incorporated herein in its entirety by reference.

### TECHNICAL FIELD

The present disclosure relates to an apparatus and a method for estimating a state of charge (SOC) of a lithium ion battery and, more particularly, to an apparatus and a method for estimating SOC of a battery (for example, a 12V lithium ion battery) supplying power for electrical loads of a vehicle.

### BACKGROUND

Eco-friendly vehicles include a high voltage battery for supplying driving power and an auxiliary battery for supplying operating power to internal electrical components or devices (electrical loads). A low voltage DC-DC converter (LDC) connected to the auxiliary battery and the electrical devices may lower a high voltage of the high voltage battery to a voltage required for charging the auxiliary battery (down conversion) under the control of a high-level controller to charge the auxiliary battery unless the voltage of the auxiliary battery exceeds a reference value.

Such an auxiliary battery may supply power for operating electrical devices such as various types of lamps, systems, electronic control units (ECUs) and the like, as well as for starting the vehicle.

Lead-acid storage batteries have commonly been used as auxiliary batteries for vehicles since they can be recharged for use even after being completely discharged. However, such a lead-acid storage battery is relatively heavy and has a low charge density, and in particular, lead-acid may have adverse environmental properties. Thus, these batteries are being replaced by lithium ion batteries for eco-friendly vehicles.

A lithium ion battery (for example, a lithium ion battery having flat voltage characteristics) has insignificant variations in open circuit voltage (OCV) according to variations in state of charge (SOC), as shown in table 1, and thus, the accuracy of a technique for estimating SOC on the basis of OCV may be significantly reduced.

TABLE 1

| SOC (%) | Lithium Ion Battery | Lead-acid Storage Battery |
|---|---|---|
| 100 | 14.53 | 13.77 |
| 95 | 13.33 | — |
| 90 | 13.32 | 13.28 |
| 85 | 13.32 | — |
| 80 | 13.32 | 12.91 |
| 75 | 13.32 | — |
| 70 | 13.32 | 12.59 |
| 65 | 13.20 | — |
| 60 | 13.16 | 12.34 |
| 55 | 13.16 | — |
| 50 | 13.16 | 12.17 |
| 45 | 13.16 | — |
| 40 | 13.16 | 12.05 |
| 35 | 13.15 | — |
| 30 | 13.14 | 11.93 |
| 25 | 13.09 | — |
| 20 | 13.01 | 11.81 |
| 15 | 12.87 | — |
| 10 | 12.82 | 11.68 |
| 5 | 12.81 | — |
| 0 | 12.32 | 11.57 |

Thus, a conventional technique for estimating SOC on the basis of OCV may be problematic in terms of accuracy due to the above-stated characteristics of the lithium ion battery.

### SUMMARY

The present disclosure has been made to solve the above-mentioned problems occurring in the prior art while advantages achieved by the prior art are maintained intact.

An aspect of the present disclosure provides an apparatus and a method for estimating a state of charge (SOC) of a vehicle battery, in which a map having a SOC corresponding to charging current recorded therein may be stored according to a charging voltage (output voltage of a low voltage DC-DC converter (LDC)), and an SOC of a lithium ion battery may be estimated on the basis of the map, whereby the SOC of the lithium ion battery can be estimated with high accuracy.

The object of the present disclosure is not limited to the foregoing object, and any other objects and advantages not mentioned herein will be clearly understood from the following description. The present disclosed concepts will be more clearly understood from exemplary embodiments of the present disclosure. In addition, it will be apparent that the objects and advantages of the present disclosure can be achieved by elements claimed in the claims and a combination thereof.

According to an aspect of the present disclosure, an apparatus for estimating a SOC of a battery for a vehicle may include: a storage for storing a map, in which a SOC corresponding to a charging current is recorded, according to a charging voltage; an LDC for charging a lithium ion battery; a current sensor for detecting a charging current of the lithium ion battery; and a controller for retrieving the map corresponding to a charging voltage of the lithium ion battery from the storage and extracting a SOC corresponding to the charging current detected by the current sensor from the retrieved map to estimate SOC of the lithium ion battery.

According to another aspect of the present disclosure, a method for estimating SOC of a battery for a vehicle may include: storing, by a storage, a map, in which a SOC corresponding to a charging current is recorded, according to a charging voltage; charging, by an LDC, a lithium ion battery; detecting, by a current sensor, a charging current of the lithium ion battery; and estimating, by a controller, a SOC of the lithium ion battery by retrieving the map corresponding to a charging voltage of the lithium ion battery from the storage and extracting a SOC corresponding to the charging current detected by the current sensor from the retrieved map.

### BRIEF DESCRIPTION OF THE DRAWINGS

The above and other objects, features and advantages of the present disclosure will be more apparent from the following detailed description taken in conjunction with the accompanying drawings:

FIG. 1 illustrates a configuration of an apparatus for estimating a state of charge (SOC) of a vehicle battery, according to an exemplary embodiment of the present disclosure;

FIG. 2 illustrates a graph in which SOC corresponding to charging current is recorded, according to an exemplary embodiment of the present disclosure; and

FIG. 3 illustrates a flowchart of a method for estimating SOC of a vehicle battery, according to an exemplary embodiment of the present disclosure.

### DETAILED DESCRIPTION

The above and other objects, features and advantages of the present disclosure will be more clearly understood from the following detailed description taken in conjunction with the accompanying drawings so that those skilled in the art to which the present disclosure pertains can easily carry out technical ideas described herein. In addition, a detailed description of well-known techniques associated with the present disclosure will be left out in order to not unnecessarily obscure the concepts of the present disclosure. Hereinafter, exemplary embodiments of the present disclosure will be described in detail with reference to the accompanying drawings.

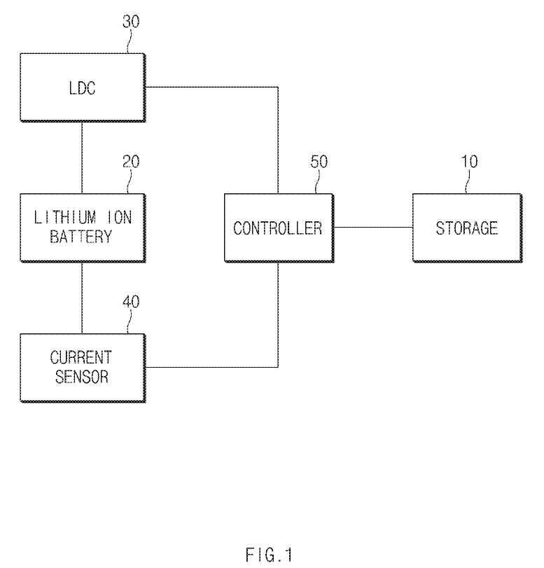

FIG. 1 illustrates a configuration of an apparatus for estimating a state of charge (SOC) of a vehicle battery, according to an exemplary embodiment of the present disclosure.

As illustrated in FIG. 1, the apparatus for estimating SOC of a vehicle battery, according to an exemplary embodiment of the present disclosure, may include a storage 10, a lithium ion battery 20, a low voltage DC-DC converter (LDC) 30, a current sensor 40 and a controller 50.

With respect to each of the aforementioned elements, first, the storage 10 may store a map, in which SOC corresponding to charging current is recorded, according to charging voltage (output voltage of the LDC). Such a map may be made, or created, on the basis of the following feature: if lithium ion batteries with different SOCs are charged with constant voltage (CV) higher than or equal to open circuit voltage (OCV), the SOCs of individual lithium ion batteries may converge on, or to, the same value when the charging is finished, or as the charging approaches completion. In other words, when the LDC 30 charges the lithium ion batteries 20, which may be auxiliary batteries, with constant voltage (CV charging method), the SOCs of individual lithium ion batteries may converge on the same value when the charging is finished, or when the charging approaches completion, regardless of initial SOCs thereof.

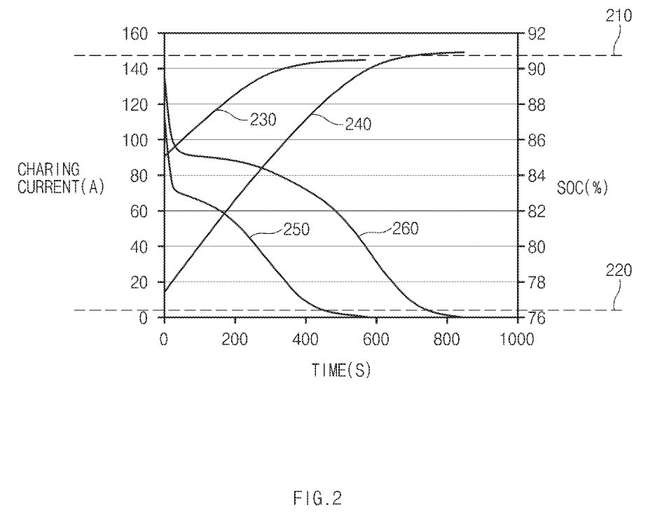

Hereinafter, with reference to FIG. 2, a map in which SOC corresponding to charging current is recorded when the output voltage of the LDC 30 is 13.5V will be detailed.

FIG. 2 illustrates a map in which SOC corresponding to charging current is recorded, according to an exemplary embodiment of the present disclosure.

In FIG. 2, “210” may indicate SOC as a convergence result when lithium ion batteries with different SOC are fully charged with 13.5V, and for example, a final SOC convergence point may be (90.8±0.5) %.

Other examples are as follows:

1) when lithium ion batteries with different SOCs are fully charged with 13.3V, a final SOC convergence point may be (35.4±0.4) %;

2) when lithium ion batteries with different SOCs are fully charged with 13.4V, a final SOC convergence point may be (78.3±0.2) %;

3) when lithium ion batteries with different SOCs are fully charged with 13.6V, a final SOC convergence point may be (97.1±0.2) %;

4) when lithium ion batteries with different SOCs are fully charged with 13.7V, a final SOC convergence point may be (97.8±0.2) %; and

5) when lithium ion batteries with different SOCs are fully charged with 13.8V, a final SOC convergence point may be (98.5±0.2) %.

Based on the above examples, it can be seen that as the charging voltage is increased, the SOCs of the lithium ion batteries is increased.

Meanwhile, “220” may indicate a minimum charging current value, and may be, for example, 0.8 A. Such a minimum charging current may be varied according to charging voltage, or may be set to be the same, regardless of charging voltage.

“230” may indicate a graph illustrating variations in SOC over time when a lithium ion battery with an SOC of 85% is charged with 13.5V. Here, the SOC of the fully charged lithium ion battery may be (90.8±0.5) %.

“240” may indicate a graph illustrating variations in SOC over time when a lithium ion battery with an SOC of 17% is charged with 13.5V. Here, the SOC of the fully charged lithium ion battery may be (90.8±0.5) %.

“250” may indicate a graph illustrating variations in charging current when a lithium ion battery with an SOC of 85% is charged with 13.5V.

“260” may indicate a graph illustrating variations in charging current when a lithium ion battery with an SOC of 17% is charged with 13.5V.

It can be seen that the graph indicated by “230” and the graph indicated by “240” include a point of inflection, or a point where the graph slopes change when approaching an asymptotic value, i.e., a point where the slope becomes gentle or lower, immediately before convergence.

With reference to FIG. 2, it can be seen that the charging current is lowered over time, and the SOC is increased and converges on “210”.

The lithium ion battery 20 may be, for example, a 12V lithium ion battery (a low voltage auxiliary battery), and may supply power to, or for, electrical loads of a vehicle.

The LDC 30 may down-convert the power of the high voltage battery to charge the lithium ion battery 20. The LDC 30 may charge the lithium ion battery 20 on the basis of a charging voltage command received from a hybrid control unit (HCU) (not shown).

The current sensor 40 may detect the charging current of the lithium ion battery 20.

The controller 50 may control the aforementioned respective elements to perform the functions thereof normally.

In particular, the controller 50 may estimate the SOC of the lithium ion battery 20, on the basis of the map, in which SOC corresponding to charging current is recorded, stored in the storage 10.

The controller 50 may retrieve the map corresponding to the output voltage of the LDC 30 from the storage 10 and extract an SOC corresponding to the charging current detected by the current sensor 40 from the retrieved map to estimate the SOC of the lithium ion battery 20.

The functions of the controller 50 may be implemented by a battery management system (BMS).

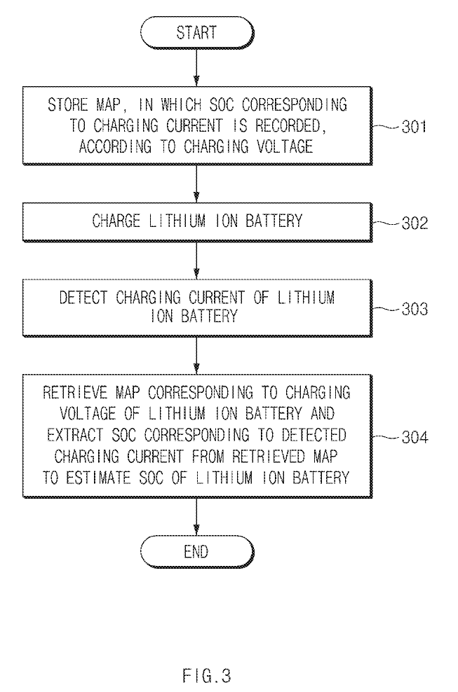

FIG. 3 illustrates a flowchart of a method for estimating SOC of a battery for a vehicle, according to an exemplary embodiment of the present disclosure.

First, the storage 10 may store a map, in which SOC corresponding to charging current is recorded, according to charging voltage in operation 301.

Next, the LDC 30 may charge the lithium ion battery 20 in operation 302.

Thereafter, the current sensor 40 may detect a charging current of the lithium ion battery 20 in operation 303.

Then, the controller 50 may retrieve the map corresponding to a charging voltage of the lithium ion battery 20 from the storage 10 and extract SOC corresponding to the charging current detected by the current sensor 40 from the retrieved map to thereby estimate SOC of the lithium ion battery 20 in operation 304.

Throughout these operations, the SOC of the lithium ion battery 20 may be estimated with high accuracy.

Meanwhile, the above-stated method according to an exemplary embodiment of the present disclosure may be written as a computer program. Codes and code segments constituting the program may easily be inferred, or implemented or created, by a computer programmer skilled in the art. In addition, the written program may be stored in a computer-readable recording medium (an information storage medium) and be read and executed by a computer, thereby implementing the method according to the exemplary embodiment of the present disclosure. The recording medium includes all types of computer-readable recording media.

As set forth above, the map, in which SOC corresponding to charging current is recorded, may be stored according to charging voltage (output voltage of the LDC), and the SOC of the lithium ion battery may be estimated on the basis of the map, whereby the SOC of the lithium ion battery can be estimated with high accuracy.

The present disclosure may be applied to eco-friendly vehicles that run on the power of an electric motor driven by a high voltage battery and include a hybrid electric vehicle (HEV), an electric vehicle (EV), a plug-in hybrid electric vehicle (PHEV), a fuel cell electric vehicle (FECV), and the like.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. An apparatus for estimating a state of charge (SOC) of a vehicle battery, the apparatus comprising:
a storage for storing a map, in which a SOC corresponding to a charging current is recorded, according to a charging voltage;
a converter for charging a lithium ion battery;
a current sensor for detecting a charging current of the lithium ion battery; and
a controller for retrieving the map corresponding to a charging voltage of the lithium ion battery from the storage and for extracting a SOC corresponding to the charging current detected by the current sensor from the retrieved map to estimate a SOC of the lithium ion battery.

2. The apparatus according to claim 1, wherein the SOC of the lithium ion battery is increased as the charging voltage is increased.

3. The apparatus according to claim 1, wherein the charging voltage is an output voltage of the converter.

4. The apparatus according to claim 1, wherein the converter is a low voltage DC-DC converter (LDC).

5. The apparatus according to claim 1, wherein the converter charges the lithium ion battery at a constant voltage.

6. The apparatus according to claim 1, wherein the lithium ion battery supplies power to an electrical load of the vehicle.

7. A method for estimating a state of charge (SOC) of a vehicle battery, the method comprising:
storing, by a storage, a map, in which SOC corresponding to a charging current is recorded, according to a charging voltage;
charging, by a converter, a lithium ion battery;
detecting, by a current sensor, a charging current of the lithium ion battery; and
estimating, by a controller, a SOC of the lithium ion battery by retrieving the map corresponding to a charging voltage of the lithium ion battery from the storage and extracting a SOC corresponding to the charging current detected by the current sensor from the retrieved map.

8. The method according to claim 7, wherein the SOC of the lithium ion battery is increased as the charging voltage is increased.

9. The method according to claim 7, wherein the charging voltage is an output voltage of the converter.

10. The method according to claim 7, wherein the converter is a low voltage DC-DC converter (LDC).

11. The method according to claim 7, wherein the converter charges the lithium ion battery at a constant voltage.

12. The method according to claim 7, wherein the lithium ion battery supplies power to an electrical load of the vehicle.
